(19) United States
(12) Patent Application Publication
(10) Pub. No.: US 2013/0341665 A1
(43) Pub. Date: Dec. 26, 2013

(54) LED (Light-Emitting Diode) Luminous Source Module

(71) Applicant: Pierre-Yves Lahary, Lyon (FR)

(72) Inventor: Pierre-Yves Lahary, Lyon (FR)

(73) Assignee: SOLVAY ACETOW GMBH, Freiburg (DE)

(21) Appl. No.: 13/995,435

(22) PCT Filed: Dec. 20, 2011
(86) PCT No.: PCT/EP2011/073339

§ 371 Date: Sep. 11, 2013

(30) Foreign Application Priority Data
Dec. 20, 2010 (FR) 10 60823

(51) Int. Cl. H01L 33/58

(52) U.S. Cl. CPC H01L 33/58
USPC 257/98

(57) ABSTRACT

A polymeric optical lens for a light-emitting diode (LED) light source module, and in particular an LED light source module comprising this polymeric optical lens, and an LED lamp comprising this module. More particularly, an optical lens for a light-emitting diode (LED) light source module comprising a polymer selected from the group consisting of cellulose and its derivatives; starch and its derivatives; alginates and their derivatives; guars and their derivatives; chitin and its derivatives; and pectin and its derivatives.

The present invention relates to a polymeric optical element such as a lens for an LED (light-emitting diode) light source module, and in particular an LED light source module comprising this optical element, and an LED lamp comprising this module.

Light-emitting diode (generally denoted by LED) lighting devices are known. Such diodes have a long service life, have a low power consumption and do not produce excessive heat.

White LEDs that are increasingly efficient and powerful, in terms of luminosity, and which can replace incandescent or halogen lamps have in particular only recently been found.

LED lamps generally comprise one or more LED (light-emitting diode) chips, and an optical system comprising one or more optical elements such as lenses. These optical elements are generally transparent, made of glass or of a polymeric material. The optical system makes it possible in particular to optimize the transmission of light generated by the LED chip(s).

New high-performance materials are constantly being sought.

For this purpose, the present invention proposes, as a first object, an optical element such as a lens for an LED (light-emitting diode) light source module, the optical element comprising at least one polymer chosen from the following polymers: cellulose and its derivatives, starch and its derivatives, alginates and their derivatives, guars and their derivatives, chitin and its derivatives and pectin and its derivatives.

As a second object, the invention proposes an LED (light-emitting diode) light source module comprising an optical system with at least one optical element as described above.

Finally, as a third object, the invention proposes an LED (light-emitting diode) lamp comprising this module.

The invention firstly relates to a polymeric optical element for an LED (light-emitting diode) light source module.

The polymer of the optical element may, for example, be one of the polymers below: cellulose, cellulose acetate, cellulose propionate, cellulose butyrate, cellulose triacetate, ethyl cellulose, hydroxy ethyl cellulose, methyl cellulose, hydroxy methyl cellulose, starch, hydroxypropyl starch, starch acetate, starch propionate, starch butyrate or mixed esters of starch, gum arabic, agar-agar, alginic acid, sodium alginate, potassium alginate, calcium alginate, gum tragacanth, guar gum and carob gum.

In particular, the polymer may be a derivative of cellulose, for example cellulose acetate, cellulose propionate, cellulose butyrate, cellulose triacetate, ethyl cellulose, hydroxy ethyl cellulose, methyl cellulose and hydroxy methyl cellulose.

According to one particular embodiment of the invention, the cellulose derivative is obtained from cellulose derived from premium wood pulp, or from cellulose derived from cotton linter. The expression “premium wood pulp” is understood to mean a wood pulp comprising at least 95% by weight of α-cellulose. The amount of α-cellulose is determined according to the ISO 692 standard. As regards the cellulose derived from cotton linter, it is preferably an acetate grade.

More particularly, the polymer may be a cellulose ester. They are generally organic, and in particular aliphatic, esters.

Advantageously, the cellulose ester has an acyl group having from 2 to 4 carbon atoms as ester group. These may be mixed esters of cellulose. Mention may be made, as an example of a suitable cellulose ester within the context of the invention, of: cellulose acetate, cellulose propionate, cellulose butyrate, cellulose acetate propionate, cellulose acetate butyrate, cellulose acetate phthalate and cellulose acetate propionate butyrate. The butyryl group forming the butyrate may be linear or branched.

Advantageously, the degree of substitution of the cellulose is between 2 and 3, preferably between 2.3 and 2.9. The degree of substitution of the cellulose is determined according to the ASTM D871-72 standard.

The intrinsic viscosity of the polymer of the invention is advantageously between 0.3 and 0.4, preferably between 0.32 and 0.35. The intrinsic viscosity is measured according to the ASTM D871-72 standard.

The polymer of the optical element may be a blend of several polymers.

Preferably, the polymer is cellulose acetate.

The optical element advantageously comprises at least 50% by weight of polymer, preferably at least 55% by weight.

According to one particular embodiment of the invention, the optical element comprises a plasticizer. Mention may be made, as examples of plasticizers, of triacetin, diethyl phthalate, dimethyl phthalate, butyl phthalyl butyl glycolate, diethyl citrate, dimethoxy ethyl phthalate, ethyl phthalyl ethyl glycolate, methyl phthalyl ethyl glycolate, n-ethyl-o/p-toluenesulfonamides, triphenyl phosphate, tricresyl phosphate, dibutoxyethyl phthalate, diamyl phthalate, tributyl citrate, tributyl acetyl citrate, tripropyl acetyl citrate, tripropionin, tributyrin, o/p-toluenesulfonamide, pentaerythritol tetraacetate, dibutyl tartrate, diethylene glycol diacetate, diethylene glycol dipropionate, dibutyl adipate, dioctyl adipate, dibutyl azelate, trichloroethyl phosphate, tributyl phosphate, di-n-butyl sebacate, dibutyl phthalate, dioctyl phthalate, butylbenzyl phthalate, 2-ethylhexyl adipate and di-2-ethylhexyl phthalate. The amount of plasticizer is advantageously between 10% and 45% by weight relative to the weight of the optical element, preferably between 20% and 40% by weight.

According to one particular embodiment of the invention, the optical element comprises a heat stabilizer (that protects against thermal and/or thermo-oxidative degradation), such as an antioxidant. Mention may be made, as examples of heat stabilizers, of glycidyl ethers, metal salts of weak acids, substituted phenols, etc. In particular, mention may be made of hydroquinone monoglycidyl or diglycidyl ethers, potassium oxalate, strontium naphthenate, resorcinol diglycidyl ether, magnesium or aluminum formate, magnesia, etc.

Mention may be made, as examples of antioxidants, of hindered phenolic antioxidants. Such antioxidants are, for example, described in patent applications WO 2004/000921 and WO 02/053633. Irganox 1076® (octadecyl 3,5-di-tert-butyl-4-hydroxyhydrocinnamate) and Irganox 1010® (tetrakis(methylene(3,5-di-tert-butyl-4-hydroxyhydrocinnamate)methane)) are examples of such antioxidants.

Mention may also be made, as examples of antioxidants, of phosphorus-containing stabilizers such as phosphites substituted by alkyl and/or aryl radicals, for example Irgafos 168® (tris-(2,4-di-tert-butylphenyl)phosphite).

According to one particular embodiment of the invention, the optical element comprises a light stabilizer.

Mention may be made, as examples of light stabilizers, of the stabilizers having at least one hindered amine unit (Hindered Amine Light Stabilizer H.A.L.S.). Such additives are, for example, described in patent applications WO 2004/000921 and WO 2005/040262.

As examples of light stabilizers, mention may also be made of UV absorbers. Such UV absorbers are in particular described in patent application WO 2004/000921. Mention may be made, as examples of UV absorbers, of oxanilides, benzophenones such as Uvinul 400® (2,4-dihydroxybenzophenone), benzotriazoles such as Tinuvin 360® (dimeric 2-hydroxyphenylbenzotriazole) or 2,2′-methylenebis[6-(2H-benzotriazol-2-yl)-4-(1,1,3,3-tetramethylbutyl)phenol], 2-hydroxyphenyltriazines such as Tinuvin 1577FF® (2,4-diphenyl-6-(2-hydroxy-4-hexyloxyphenyl)-s-triazine) and Tinuvin 234® (2-(2H-benzotriazol-2-yl)-4,6-bis(1-ethyl-1-phenylethyl)phenol).

The optical element may also comprise one or more additives chosen from fillers, dyes, pigments, antistatic agents, surfactants, lubricants, dispersants, flame retardants, molding aids and impact modifiers. This list is not limiting.

The optical element is an object/article obtained by shaping the constituent compound(s) of the optical element. It may for example be articles chosen from the group consisting of injected or molded parts. Advantageously, the optical element has a thickness between 0.4 and 40 mm, preferably between 1 and 30 mm, more preferably still between 2 and 25 mm.

The optical element is advantageously a lens. It may be a Fresnel lens. It may be convex or concave.

Preferably, the optical element of the invention is optically transparent, that is to say that it has a light transmittance of at least 88% according to the ASTM D1003 standard.

The optical element may be prepared according to any known process for preparing an optical element, in particular a lens.

It is possible, initially, to prepare granules consisting of the constituent compound(s) of the optical element, for example by extrusion in the form of rods, of the polymer or of a composition comprising the polymer that forms the optical element; which rods are then cut in order to form granules. The additives such as plasticizers, stabilizers, etc. may be introduced at different locations of the extrusion device, for example at different locations of a twin-screw extruder. The granules may then be introduced into a transformation and shaping device, such as a device for molding, injection molding, extrusion, cast molding, etc. These processes are known to a person skilled in the art.

The invention also relates to an LED (light-emitting diode) light source module comprising an optical system having at least one optical element as described above.

This LED (light-emitting diode) light source module comprises:
at least one LED (light-emitting diode) chip, encapsulated in an encapsulant material such as an epoxy resin;
at least optical system comprising at least one optical element as described above; and
two electrodes (anode and cathode).

The structure of the LED (light-emitting diode) light source modules are known to a person skilled in the art.

The LED (light-emitting diode) chip of the LED light source module of the invention may be any chip that emits in the visible, ultraviolet or infrared.

The structure of the LED (light-emitting diode) chip comprises a layer of semiconductor material. For example, the LED chip may comprise layers of semiconductor material from columns III and IV of the Periodic Table of the Elements, such as GaAs, GaAlAs, GaN, InGaN, GaP etc., or layers of semiconductor material from columns II to VI of the Periodic Table of the Elements, such as ZnSe, ZnSSe, CdTe, etc., or layers of semiconductor material from columns IV and V of the Periodic Table of the Elements, such as SiC. The LED chip may also comprise other layers.

The LED (light-emitting diode) light source module of the invention may comprise a plurality of LED chips.

The structure of the optical systems of the LED (light-emitting diode) light source modules is known to a person skilled in the art. It may be complex and varied.

The optical system makes it possible in particular to optimize the transmission of light generated by the LED chip(s) of the module.

The optical system comprises at least one optical element. It may comprise a combination of several optical elements.

The optical system may have various shapes and various arrangements. These shapes and these arrangements are known to a person skilled in the art.

According to one particular embodiment of the invention, the optical element is a lens which covers the LED chip. It may, for example, be in the shape of a bead, of a dome, etc.

According to one particular embodiment of the module of the invention, the optical element is a collimator, a collector or a diverger. A collimator is an optical element which concentrates the luminous flux.

The invention finally relates to an LED (light-emitting diode) lamp comprising at least the LED light source module of the invention.

According to another particular embodiment of the invention, the lamp also comprises a bulb or a wrap-around diffuser covering the LED light source module. This bulb or this wrap-around diffuser generally has a role of protecting the LED light source module.

The bulb may be of various shapes. It may for example be round, curved, cylindrical, etc.

According to this particular embodiment of the invention, the bulb or the wrap-around diffuser preferably comprises at least one polymer chosen from the following polymers: cellulose and its derivatives, starch and its derivatives, alginates and their derivatives, guars and their derivatives, chitin and its derivatives and pectin and its derivatives. Everything which was described above regarding the polymer of the optical element applies here for the bulb or the wrap-around diffuser.

The optical element of the invention has very good properties for its application in LED light source modules. Specifically, it is transparent (it has a high light transmittance), lighter than glass, and it has good mechanical properties, in terms of modulus in particular. It can be obtained in various sizes and shapes, and it is suitable for mass production. Another advantage of the optical element of the invention is that it is made from a bio-based material.

Other details or advantages of the invention will become more clearly apparent in light of the examples given below.

### EXAMPLES

### Example 1

Disks of plasticized cellulose acetate for the optical element in an LED light source module were prepared in this example.

A cellulose acetate having a degree of substitution of 2.45 and an intrinsic viscosity of 0.342 in accordance with the ASTM D871-72 standard was plasticized by 30% by weight of triacetin sold by the company Eastman, by extrusion.

This material was prepared under the following conditions. An Evolum 32® co-rotating twin-screw extruder sold by the company Clextral, having a diameter D=32 mm and a ratio of length to diameter L/D=44, was used. The cellulose acetate powder was introduced via the feed hopper and the liquid plasticizer (triacetin) was introduced at the start of the screw via a specific feed channel. The processing conditions applied are the following:
rotational speed of the screws: 100 rpm;
throughput: 10 kg/h;
temperature profile from the feed hopper to the die: from 80 to 160° C.

On leaving the extruder, the rod of plasticized cellulose acetate was granulated.

The granules thus prepared were then shaped by injection molding with an Arburg 350-90® press (mold closing force of 35 tonnes). Disks of plasticized cellulose acetate having a diameter of 85 mm and a thickness of 3 mm were obtained under the following conditions:
temperature profile of the single-screw extruder from the feed hopper: 160-172-172-179° C.;
mold temperature: 70° C.
length of the injection cycle: 37.8 s.

A Konica Minolta CM-5® spectrophotometer was then used in order to measure the transmittance in accordance with the ASTM D1003 standard. A transmittance of 94.3% at 700 nm was obtained for this 3 mm thick sample.

### Example 2

In this example, a cellulose acetate butyrate CAB 381-2® sold by the company Eastman was plasticized by 10% by weight of triacetin sold by the company Aldrich. The following additives were added to the formulation:
antioxidants:
   0.5% by weight of Irganox 1010® (tetrakis(methylene-(3,5-di-(tert)-butyl-4-hydrocinnamate))methane) (sold by the company Ciba);
   0.5% by weight of Irgafos 168® (tris(2,4-di-tert-butylphenyl)phosphite) (sold by the company Ciba);
UV absorber:
   0.3% by weight of Tinuvin 234® (2-(2H-benzotriazol-2-yl)-4,6-bis(1-ethyl-1-phenylethyl)phenol) (sold by the company Ciba).

1. An optical element for a light-emitting diode (LED) light source module, comprising at least one polymer selected from the group consisting of cellulose and its derivatives; starch and its derivatives; alginates and their derivatives; guars and their derivatives; chitin and its derivatives; and pectin and its derivatives.

2. The optical element for an LED light source module according to claim 1, wherein said polymer is an ester.

3. The optical element for an LED light source module according to claim 1, wherein said polymer is a cellulose ester.

4. The optical element for an LED light source module according to claim 1, wherein said polymer is cellulose acetate.

5. The optical element for an LED light source module according to claim 1, comprising at least 50% by weight of said polymer.

6. The optical element for an LED light source module according to claim 1, comprising a plasticizer.

7. The optical element for an LED light source module according to claim 1, comprising a heat stabilizer.

8. The optical element for an LED light source module according to claim 1, comprising a light stabilizer.

9. The optical element for an LED light source module according to claim 1, being a lens.

10. A light-emitting diode (LED) light source module, comprising:
at least one light-emitting diode (LED) chip, encapsulated in an encapsulant material;
an optical system comprising at least one optical element according to claim 1; and
two electrodes being an anode and a cathode.

11. The LED light source module according to claim 10, wherein said optical element is a lens covering said LED chip.

12. The LED light source module according to claim 10, wherein said optical element is a collimator, a collector, or a diverger.

13. The LED light source module according to claim 10, comprising several LED chips.

14. A light-emitting diode (LED) lamp, comprising at least the LED light source module according to claim 10.

15. The LED lamp according to claim 14, further comprising a wrap-around diffuser or a bulb covering said LED light source module.

16. The LED lamp according to claim 15, wherein said bulb or said wrap-around diffuser comprises at least one polymer selected from the group consisting of cellulose and its derivatives; starch and its derivatives; alginates and their derivatives; guars and their derivatives; chitin and its derivatives; and pectin and its derivatives.
